(19) United States
(12) Patent Application Publication
(10) Pub. No.: US 2010/0232210 A1
(43) Pub. Date: Sep. 16, 2010

(54) SEMICONDUCTOR MEMORY DEVICE AND MANUFACTURING METHOD THEREOF

(75) Inventors: Takeshi KAJIYAMA, Yokohama-shi (JP); Yoshiaki ASAO, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/723,349

(22) Filed: Mar. 12, 2010

(30) Foreign Application Priority Data
Mar. 13, 2009 (JP) 2009-060928

(51) Int. Cl. G11C 11/00; G11C 7/00; H01L 21/8239

(52) U.S. Cl. 365/148; 365/210.1; 438/238; 257/E21.645

(57) ABSTRACT

A semiconductor memory device includes variable resistance elements arranged in a memory area and configured to store data according to a resistance variation, each of the variable resistance elements having a first terminal electrically connected to a first line and a second terminal electrically connected to a second line, and dummy elements arranged in the memory area, formed of the same material as the variable resistance element and electrically isolated.

### CROSS-REFERENCE TO RELATED APPLICATIONS

This application is based upon and claims the benefit of priority from prior Japanese Patent Application No. 2009-060928, filed Mar. 13, 2009, the entire contents of which are incorporated herein by reference.

### BACKGROUND OF THE INVENTION

1. Field of the Invention

This invention relates to a semiconductor memory device and a manufacturing method thereof, and for example, a semiconductor memory device having variable resistance elements used as memory elements.

2. Description of the Related Art

Recently, semiconductor memory devices using variable resistance elements as memory elements, for example, magnetic random access memories (MRAMs) have received much attention and have been developed. The MRAM is a device that performs a memory operation by storing “1” or “0” information in a memory cell by using the magnetoresistive effect. Since the MRAM has a feature of a combination of nonvolatility, high-speed operation, high integration density and high reliability, it can potentially be regarded as a replacement for a static random access memory (SRAM), pseudo SRAM (PSRAM) or dynamic random access memory (DRAM).

A large number of MRAMs using elements exhibiting a tunneling magnetoresistive (TMR) effect among the magnetoresistive effects have been reported. As the TMR effect element, it is common practice to use a magnetic tunnel junction (MTJ) element that has a laminated structure comprising two ferromagnetic layers and a nonmagnetic layer sandwiched therebetween, and that utilizes a variation in the magnetic resistance due to the spin polarization tunneling effect.

The operation of writing data in the MRAM is performed by, for example, directly passing a write current through the MTJ element and changing the magnetization arrangement, that is, the resistance of the MTJ element according to the direction of the write current. In such a spin injection write method, it is possible to further reduce the write current as the MTJ element is made smaller.

However, when the MTJ element is miniaturized, the shape of the MTJ element will vary. A variation in the magnetic characteristic of the MTJ element due to the shape variation becomes larger and the operation margin of the MRAM becomes smaller at the write or read operation.

Further, as the related art of this field, a technique for enhancing the reliability of a semiconductor memory device by reducing the current density of a line used to apply a magnetic field to the magnetoresistive element exists (see Jpn. Pat. Appln. KOKAI Publication No. 2004-119478).

### BRIEF SUMMARY OF THE INVENTION

According to an aspect of the present invention, there is provided a semiconductor memory device comprising:

variable resistance elements arranged in a memory area and configured to store data according to a resistance variation, each of the variable resistance elements having a first terminal electrically connected to a first line and a second terminal electrically connected to a second line; and

dummy elements arranged in the memory area, formed of the same material as the variable resistance element and electrically isolated.

According to an aspect of the present invention, there is provided a manufacturing method of a semiconductor memory device, the method comprising:

forming contact plugs in a first insulating layer;

sequentially depositing a variable resistance material and contact material on the first insulating layer and the contact plugs;

forming a resist pattern including first resists arranged with distances between adjacent first resists set equal on the contact material; and

etching the contact material and the variable resistance material with the resist pattern used as a mask to form variable resistance elements electrically connected to the contact plugs and dummy elements arranged on the first insulating layer.

### BRIEF DESCRIPTION OF THE SEVERAL VIEWS OF THE DRAWING

FIG. 1 shows the layout of an ideal MTJ element pattern according to a first embodiment of this invention.

FIG. 2 is a plan view showing the configuration of an MRAM according to the first embodiment.

FIG. 3 is a cross-sectional view showing the MRAM taken along the line A-A′ of FIG. 2.

FIG. 4 is a cross-sectional view showing the MRAM taken along the line B-B′ of FIG. 2.

FIG. 5 is a cross-sectional view showing the MRAM taken along the line C-C′ of FIG. 2.

FIG. 6 is a cross-sectional view showing the configuration of one MTJ element 23.

FIG. 7 is a cross-sectional view showing a manufacturing step of the MRAM according to the first embodiment.

FIG. 8 is a cross-sectional view showing a manufacturing step of the MRAM that follows the step of FIG. 7.

FIG. 9 is a cross-sectional view showing a manufacturing step of the MRAM that follows the step of FIG. 8.

FIG. 10 is a cross-sectional view showing a manufacturing step of the MRAM that follows the step of FIG. 9.

FIG. 11 is a cross-sectional view showing a manufacturing step of the MRAM that follows the step of FIG. 10.

FIG. 12 is a cross-sectional view showing a manufacturing step of the MRAM that follows the step of FIG. 11.

FIG. 13 is a cross-sectional view showing a manufacturing step of the MRAM that follows the step of FIG. 12.

FIG. 14 is a cross-sectional view showing a manufacturing step of the MRAM that follows the step of FIG. 13.

FIG. 15 is a cross-sectional view showing a manufacturing step of the MRAM that follows the step of FIG. 14.

FIG. 16 is a cross-sectional view showing a manufacturing step of the MRAM that follows the step of FIG. 15.

FIG. 17 is a cross-sectional view showing a manufacturing step of the MRAM that follows the step of FIG. 16.

FIG. 18 is a cross-sectional view showing a manufacturing step of the MRAM that follows the step of FIG. 17.

FIG. 19 is a plan view showing the configuration of an MRAM according to a second embodiment of this invention.

FIG. 20 is a cross-sectional view showing the MRAM taken along the line A-A′ of FIG. 19.

FIG. 21 is a cross-sectional view showing the MRAM taken along the line C-C′ of FIG. 19.

FIG. 22 shows the layout of an ideal MTJ element pattern according to a third embodiment of this invention.

FIG. 23 is a plan view showing the configuration of an MRAM according to the third embodiment.

FIG. 24 is a cross-sectional view showing the MRAM taken along the line A-A′ of FIG. 23.

FIG. 25 is a cross-sectional view showing the MRAM taken along the line B-B′ of FIG. 23.

### DETAILED DESCRIPTION OF THE INVENTION

The embodiments of the present invention will be described hereinafter with reference to the accompanying drawings. In the description which follows, the same or functionally equivalent elements are denoted by the same reference numerals, to thereby simplify the description.

### First Embodiment

Various types of memories, such as a magnetic random access memory (MRAM), resistive random access memory (ReRAM) and phase-change random access memory (PCRAM) can be used as a resistance-change memory. In this embodiment, an example in which an MRAM is used as the resistance-change memory is explained. The MRAM comprises an MTJ element utilizing a tunneling magnetoresistive (TMR) effect as a memory element (variable resistance element) and stores information according to the magnetization state of the MTJ element.

Generally, memory cells configuring the MRAM are each configured by one MTJ element and one transistor. In this case, the distance between two MTJ elements adjacent in a Y direction in which word lines extend corresponds to one line and the pattern thereof becomes dense. On the other hand, since two transistors or contact plugs are arranged between two MTJ elements adjacent in an X direction in which bit lines extend, the pattern thereof becomes coarse. That is, the pattern of the MTJ elements in the X direction is approximately set to an isolated pattern.

The dimensional controllability of a processed pattern tends to become higher in the case of a regular dense pattern in comparison with an isolated pattern in the operation of forming a pattern by lithography. In an MRAM that requires suppression of a resistance variation of the MTJ element, the isolated pattern becomes disadvantageous.

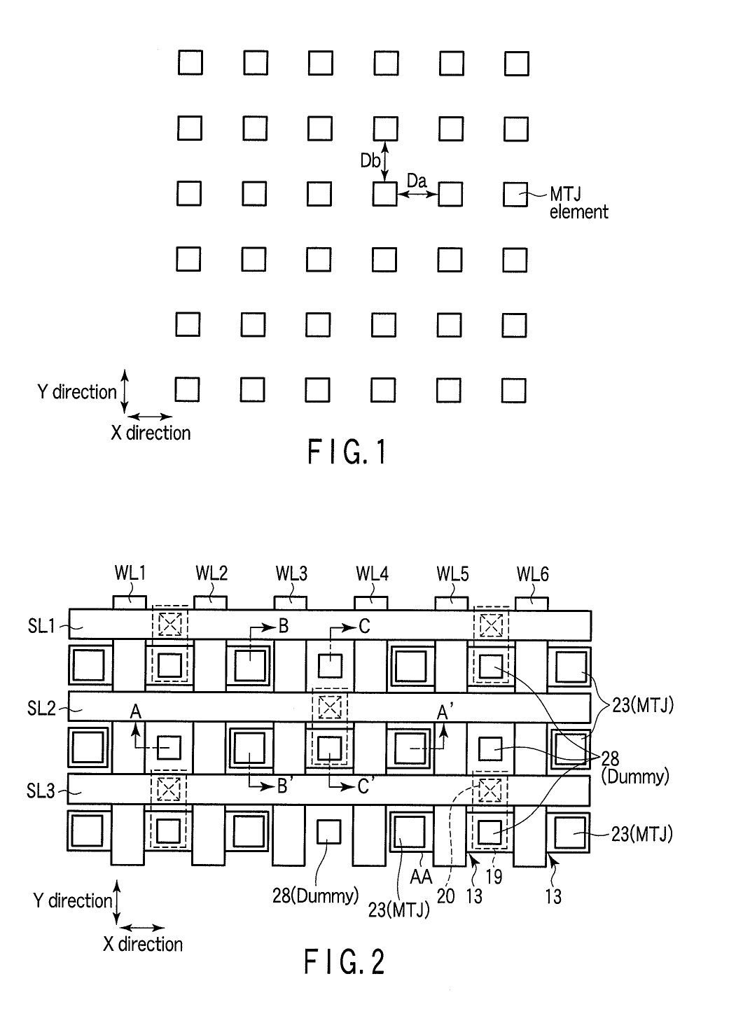

The layout of an ideal MTJ element pattern is shown in FIG. 1. The layout of FIG. 1 is a lattice-form dense pattern (mesh form dense pattern) in which the distances between elements are equal in the X and Y directions. If the distance between the elements in the X direction is set to Da and the distance between the elements in the Y direction is set to Db, then Da=Db. In the above dense pattern, since the distance between the adjacent MTJ elements is short and the element arrangement is uniform, an influence caused by the interference of light from the surroundings at the time of a lithography process tends to be made uniform and a pattern with elements of uniform sizes can be easily formed. Further, the resist profile (shape of cross section) tends to be made vertical and a variation in the shape of the element becomes small.

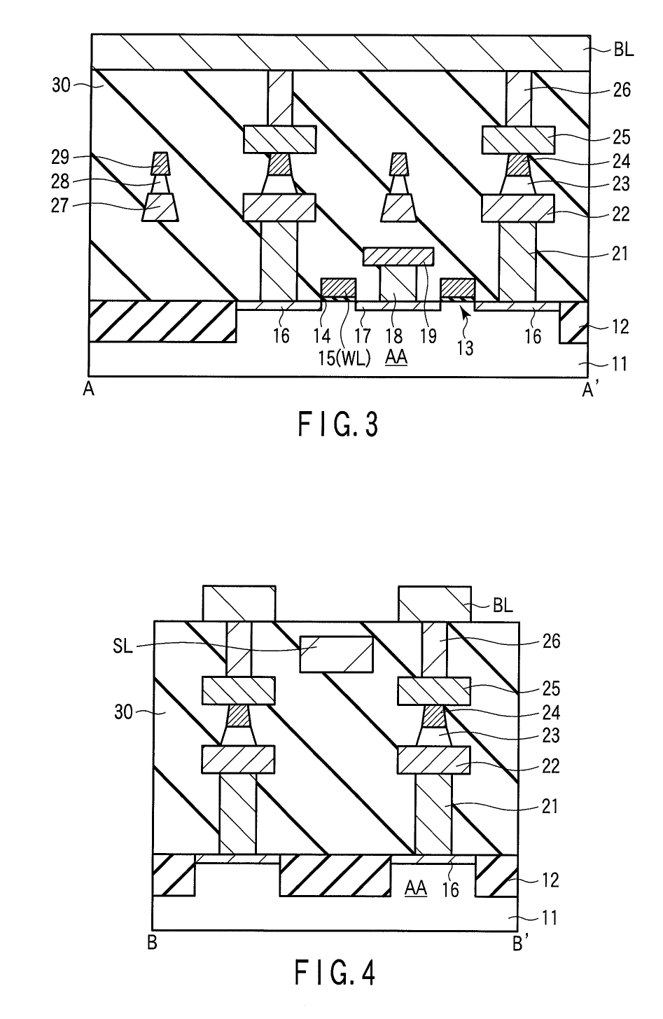

FIG. 2 shows an example in which the ideal pattern of FIG. 1 is applied to an MRAM, and is a plan view showing the configuration of the MRAM. FIG. 3 is a cross-sectional view showing the MRAM taken along the line A-A′ of FIG. 2. FIG. 4 is a cross-sectional view showing the MRAM taken along the line B-B′ of FIG. 2. FIG. 5 is a cross-sectional view showing the MRAM taken along the line C-C′ of FIG. 2. FIG. 2 is a plan view showing a memory area of the MRAM.

When the ideal pattern of FIG. 1 is applied to an MRAM, dummy elements each of which is not used as a memory element and has the same structure as the MTJ element are arranged between word lines WL. However, if the upper and lower portions of the dummy elements are not connected, no particular problem occurs in the operation of the MRAM.

A P-type semiconductor substrate 11 comprises an element isolation insulating layer 12 in a surface area thereof, and areas in which the element isolation insulating layer 12 is not formed are used as active areas (element areas) AA in which elements are formed. For example, the element isolation insulating layer 12 is configured by a shallow trench isolation (STI) structure. As the STI structure 12, a silicon oxide (SiO₂) is used, for example.

Each active area AA is a rectangular form whose longitudinal direction is set in the X direction, for example, and the active areas are arranged with equal distances set therebetween (at equal intervals corresponding to two word lines) in the X direction. Further, two active areas AA adjacent in the Y direction are shifted by a distance corresponding to two word lines in the X direction. In other words, if the active areas AA arranged in the X direction are set as one row, the active areas AA of two adjacent rows are arranged in a zigzag form. In each active area AA, two selection transistors 13 are provided, and therefore, the active area AA intersects with two word lines WL.

For example, the selection transistor 13 is configured by an N-channel metal oxide semiconductor field effect transistor (MOSFET). That is, in the active area AA, first and second diffusion regions (source/drain regions) 16 and 17 are separately provided. The first and second source/drain regions 16 and 17 are configured by N⁺-type diffusion regions each formed by doping an N-type impurity (phosphorus (P), arsenic (As) or the like) at high concentration into the semiconductor substrate 11. Above the active area AA between the first and second source/drain regions 16 and 17, a gate electrode 15 extending in the Y direction is provided with a gate insulating film 14 disposed therebetween. The gate electrode 15 functions as a word line WL. Thus, the first selection transistor 13 is formed. The second selection transistor 13 formed on the same active area AA commonly has the source/drain region 17 and is serially connected with the first selection transistor 13.

On the source/drain region 17 commonly used by the two selection transistors 13, a contact plug 18 is formed. A lead line 19 extending in the Y direction is formed on the contact plug 18. A contact plug 20 is formed on the end portion of the lead line 19. First lines (source lines SL) extending in the X direction are formed on the contact plugs 20.

On each source/drain region 16, a contact plug 21 is formed. A lower electrode 22 is formed on the contact plug 21. An MTJ element 23 is formed on the lower electrode 22. The plane shape of the MTJ element 23 is not particularly limited and may be a circle, ellipse, square or other polygon. Further, the plane shape may be set to a form obtained by rounding the corners of a polygon or a form with partly cut-away corner portions of the polygon.

A contact layer 24 is formed on each MTJ element 23. An upper electrode 25 is formed on the contact layer 24. A contact plug 26 is formed on the upper electrode 25. Second lines (bit lines BL) extending in the X direction are provided on the respective contact plugs 26. As is clearly shown in FIGS. 3 and 4, the bit line BL is arranged above the MTJ element 23 and between the source lines SL as the uppermost layer. However, in the layout shown in FIG. 2, the bit lines BL are not shown so that the layout of the MTJ elements and dummy elements can be easily understood. A gap between the semiconductor substrate 11 and the bit lines BL is filled with an interlayer insulating layer 30. As the interlayer insulating layer 30, for example, silicon oxide (SiO₂) is used.

Dummy elements 28 are each arranged between the two MTJ elements 23 adjacent in the X direction. The dummy element 28 is arranged at the same height as the MTJ element 23 and provided in an isolated form in the interlayer insulating layer 30. That is, the dummy element 28 is not electrically connected to any lint and is electrically isolated. Further, as shown in FIG. 2, all of the dummy elements 28 are arranged in a memory area in which the MTJ elements 23 are arranged.

The dummy element 28 is sandwiched between the lower electrode 27 and the upper electrode 29. The dummy element 28 has the same laminated structure as the MTJ element 23, that is, it is formed of the same material as that of the MTJ element 23. Further, the lower electrode 27 and upper electrode 29 are formed of the same materials as those of the lower electrode 22 and contact layer 24 that sandwich the MTJ element 23. The plane shape of the dummy element 28 is the same as that of the MTJ element 23. Further, the size of the dummy element 28 is smaller than that of the MTJ element 23.

The MTJ element array is arranged in a stripe form along the Y direction and each line configuring the stripe is configured by plural MTJ elements 23 arranged in the Y direction. Also, the dummy element array is arranged in a stripe form in the Y direction and each line configuring the stripe is configured by plural dummy elements 28 arranged in the Y direction. Further, the lines of the MTJ elements 23 and the lines of the dummy elements 28 are alternately arranged in the X direction. An element array comprising a combination of the MTJ elements 23 and dummy elements 28 is a lattice-form dense pattern as shown in FIG. 1.

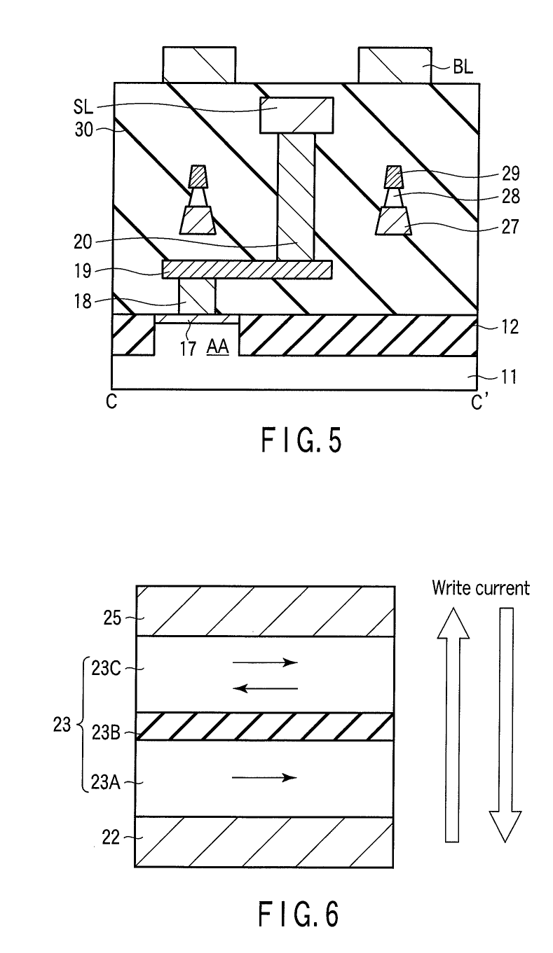

FIG. 6 is a cross-sectional view showing the configuration of one MTJ element 23. The layer structure of the dummy element 28 is the same as that of the MTJ element 23 of FIG. 6.

The MTJ element 23 has a laminated structure of the lower electrode 22, fixed layer (that is also referred to as a reference layer) 23A, intermediate layer (nonmagnetic layer) 23B, recording layer (that is also referred to as a free layer) 23C, contact layer 24 (not shown) and upper electrode 25 that are sequentially laminated in this order. The lamination order of the fixed layer 23A and recording layer 23C may be reversed. The contact layer 24, lower electrode 22 and upper electrode 25 are formed of conductive layers.

The magnetization (or spin) direction of the recording layer 23C can be varied (reversed). The magnetization direction of the fixed layer 23A is invariable (fixed). The term of “the magnetization direction of the fixed layer 23A is invariable” means that the magnetization direction of the fixed layer 23A is kept unchanged when a magnetization reversing current used to reverse the magnetization direction of the recording layer 23C is passed through the fixed layer 23A. Therefore, the MTJ element 23 comprising the recording layer 23C whose magnetization direction is variable and the fixed layer 23A whose magnetization direction is invariable can be realized by using a magnetic layer having a large reverse current as the fixed layer 23A and a magnetic layer having a reverse current smaller than that of the fixed layer 23A as the recording layer 23C in the MTJ element 23. When a reverse of the magnetization direction is caused by spin polarization electrons, the reverse current varies in proportion to the attenuation constant, anisotropic magnetic field and volume, and therefore, a difference can be made between the reverse currents of the recording layer 23C and fixed layer 23A by adequately adjusting the above values. Further, as a method for fixing the magnetization direction of the fixed layer 23A, a method for fixing the magnetization direction of the fixed layer 23A by providing an anti-ferromagnetic layer (not shown) in a position adjacent to the fixed layer 23A and utilizing the exchange coupling between the fixed layer 23A and the anti-ferromagnetic layer can be used.

The direction of easy magnetization of the recording layer 23C and fixed layer 23A may be perpendicular with respect to the film surface (or the laminated layer surface) (that is hereinafter referred to as perpendicular magnetization) or may be parallel to the film surface (that is hereinafter referred to as in-plane magnetization). The magnetic layer of perpendicular magnetization has magnetic anisotropy in the perpendicular direction with respect to the film surface, and the magnetic layer of in-plane magnetization has magnetic anisotropy in the in-plane direction. If the perpendicular magnetization type layer is used, it is not necessary to adjust the element shape in order to decide the magnetization direction, unlike the in-plane type layer, and the perpendicular magnetization type layer is suitable for miniaturization.

It is preferable to form the recording layer 23C and fixed layer 23A by use of a magnetic material having a high coercive force, for example, a magnetic anisotropic energy density of 1×10⁶ erg/cc or more. The intermediate layer 23B is formed of a nonmagnetic material, and specifically, it can be formed of an insulator, semiconductor, metal or the like, for example. The intermediate layer 23B is called a tunnel barrier layer when it is formed of an insulator or semiconductor and is called a spacer layer when it is formed of a metal.

Each of the fixed layer 23A and recording layer 23C is not limited to a single layer as shown in the drawing and may have a laminated structure comprising a plurality of magnetic layers. Further, each of the fixed layer 23A and recording layer 23C may be formed of a three-layered structure of first magnetic layer/nonmagnetic layer/second magnetic layer and have an anti-ferromagnetic coupling structure in which the first and second magnetic layers are magnetically coupled (exchange-coupled) with the magnetization directions thereof set in an anti-parallel state or a ferromagnetic coupling structure in which the first and second magnetic layers are magnetically coupled (exchange-coupled) with the magnetization directions thereof set in a parallel state.

Further, the MTJ element 23 may have a double-junction structure. The MTJ element 23 with the double-junction structure has a laminated structure of a first fixed layer, first intermediate layer, recording layer, second intermediate layer and second fixed layer that are laminated in this order. The double-junction structure has an advantage in that a reverse magnetization direction of the recording layer 23C can be easily controlled by spin injection.

The operation of writing data in the MTJ element 23 is performed by a spin injection method for supplying a write current to the MTJ element 23. Further, the MTJ element 23 is set into a low-resistance state or high-resistance state by changing the direction of a write current according to data.

At the time of the parallel state (low-resistance state) in which the magnetization directions of the fixed layer 23A and recording layer 23C are set parallel, the resistance of the MTJ element 23 becomes minimum and this state is set as “0” data. On the other hand, at the time of the anti-parallel state (high-resistance state) in which the magnetization directions of the fixed layer 23A and recording layer 23C are set anti-parallel, the resistance of the MTJ element 23 becomes maximum and this state is set as “1” data.

The data read operation is performed by supplying a read current to the MTJ element 23. If the resistance in the parallel state is set to R0 and the resistance in the anti-parallel state is set to R1, a value defined by “(R1−R0)/R0” is called a magnetoresistive ratio (MR ratio). The magnetoresistive ratio differs depending on the process condition or material configuring the MTJ element 23 and may be set to a value ranging from approximately several ten % to several hundred %. Information stored in the MTJ element 23 is read by detecting the magnitude of a read current caused by the MR ratio. A read current flowing through the MTJ element 23 at the read operation time is set to a current value that is sufficiently smaller than a current that causes the magnetization direction of the MTJ element 23 to be reversed by spin injection.

(Manufacturing Method)

Next, a manufacturing method of the MRAM according to the first embodiment is explained with reference to the accompanying drawings.

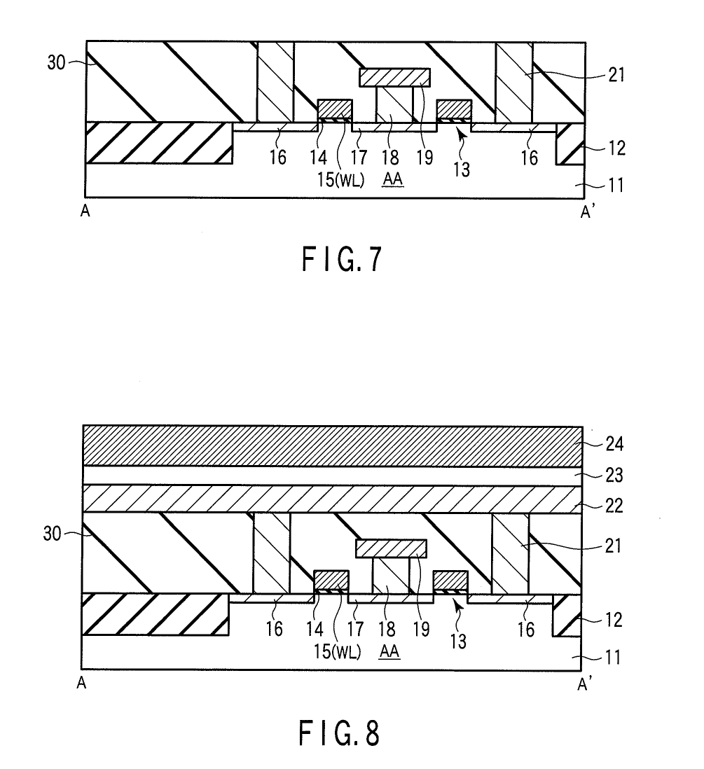

As shown in FIG. 7, an element isolation insulating layer 12 and active area AA are formed on a P-type semiconductor substrate 11. Then, two selection transistors 13 commonly using one diffusion region 17 are formed in the active area AA by a well known method. Next, an interlayer insulating layer 30 is deposited on the entire surface of the device.

Subsequently, a contact plug 18 is formed on the diffusion region 17 in the interlayer insulating layer 30. Next, a lead line 19 extending in the Y direction is formed on the contact plug 18. After this, an interlayer insulating layer 30 is further laminated. Then, contact plugs 21 are formed on diffusion regions 16 that are not commonly used by adjacent transistors in the interlayer insulating layer 30. The upper surface of the contact plug 21 is set higher than the upper surface of the lead line 19.

Next, as shown in FIG. 8, a lower electrode 22, MTJ laminated film 23 and contact layer 24 are sequentially deposited in this order on the entire surface of the device. As the lower electrode 22 and contact layer 24, for example, tantalum (Ta) is used.

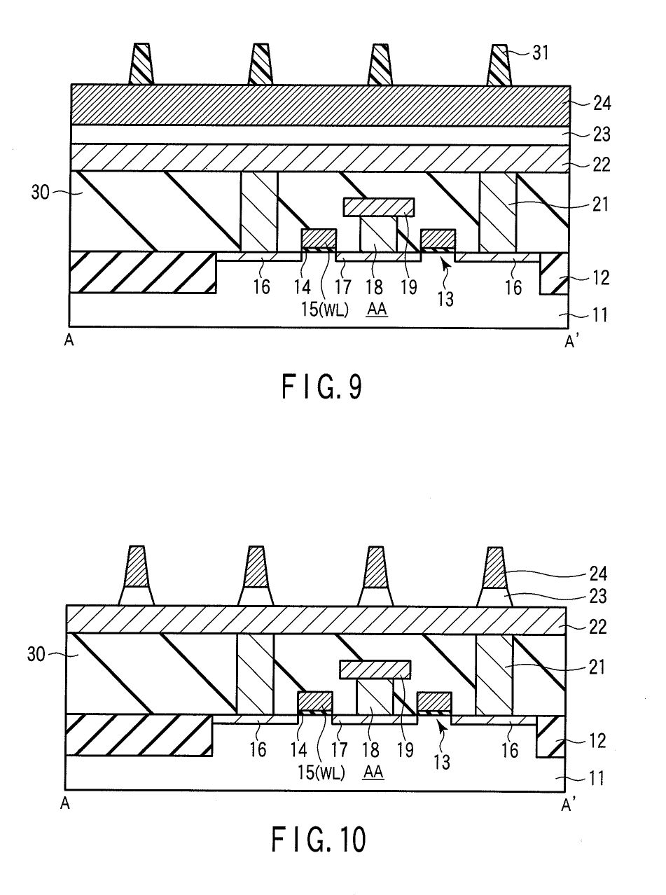

Then, as shown in FIG. 9, a resist pattern having the same pattern as that of FIG. 1 and formed of a plurality of resists 31 arranged in a lattice form is formed on the contact layer 24. Each of the resists 31 has the same plane shape as that of the MTJ element 23. Further, as described before, the resist pattern is formed to leave the resists that are not originally required above the contact plug 18 and STI 12. As a result, MTJ elements 23 are formed above the contact plugs 21 and dummy elements 28 are formed above the other regions.

Next, as shown in FIG. 10, the contact layer 24 and MTJ laminated film 23 are processed by, for example, a reactive ion etching (RIE) method with the resists 31 used as a mask. The etching process is performed by first processing the contact layer 24 by the RIE method with the resists 31 used as a mask and then processing the MTJ laminated film 23 by the RIE method again with the contact layer 24 used as a hard mask after removing the resists 31. As a result, an element array having the lattice-form pattern shown in FIG. 1 and comprising a plurality of MTJ elements 23 and a plurality of dummy elements 28 is formed.

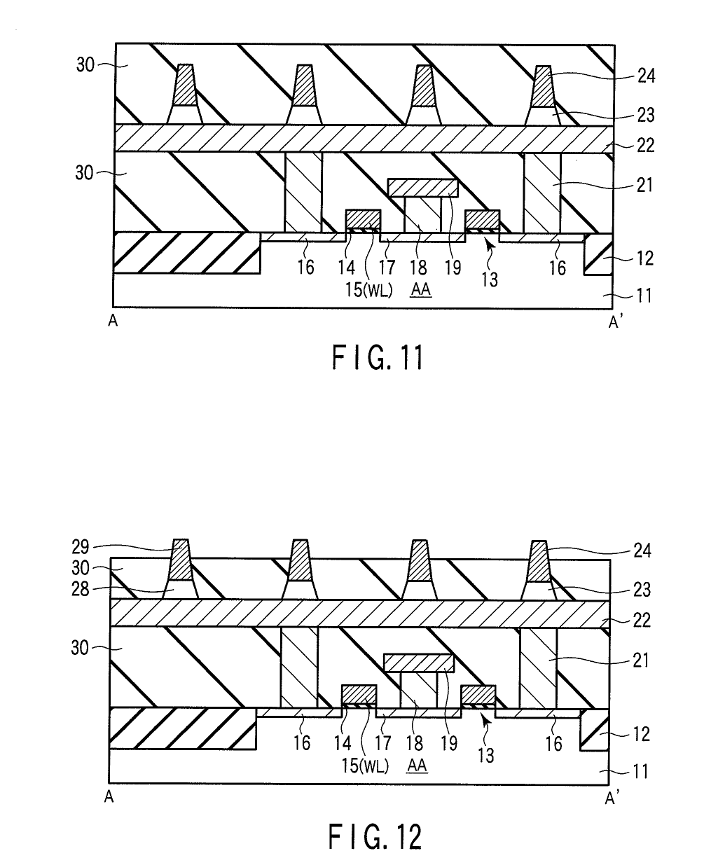

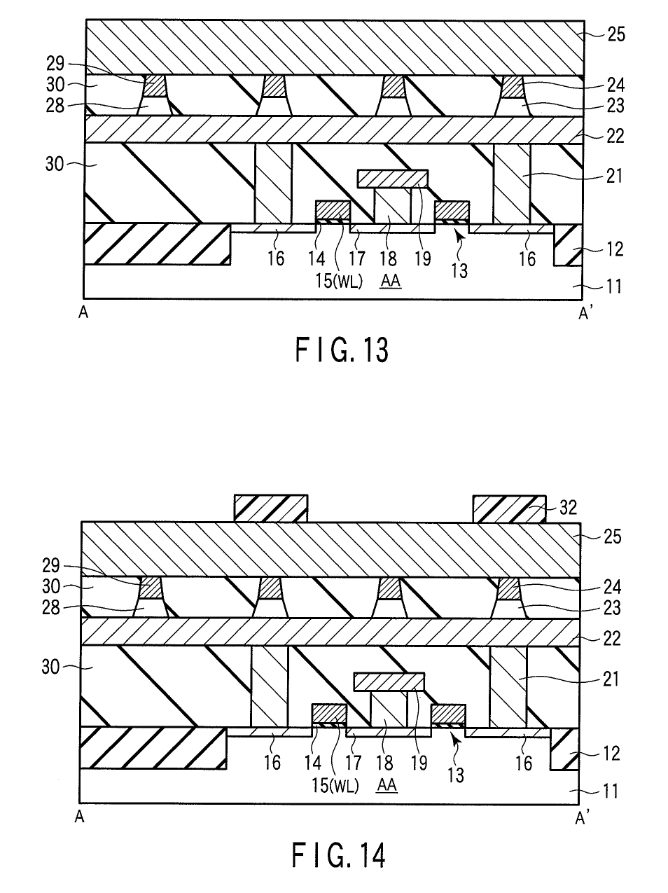

Next, as shown in FIG. 11, an interlayer insulating layer 30 is deposited on the entire surface of the device to embed the MTJ elements 23 and dummy elements 28 therein and then the interlayer insulating layer 30 is made flat by a chemical mechanical polishing (CMP) method. Then, as shown in FIG. 12, the interlayer insulating layer 30 is etched back until the upper portions of the contact layers 24 are exposed. Subsequently, as shown in FIG. 13, an upper electrode 25 is deposited on the entire surface of the device. Thus, the upper electrode 25 and contact layers 24 are electrically connected. As the upper electrode 25, for example, tantalum (Ta) is used.

Then, as shown in FIG. 14, a plurality of resists 32 are formed only in portions corresponding to forming regions of MTJ elements 23 on the upper electrode 25 by a lithography process. Each of the resists 32 has the same plane shape as that of a desired upper electrode 25. At this time, resists 32 are not formed above the dummy elements 28.

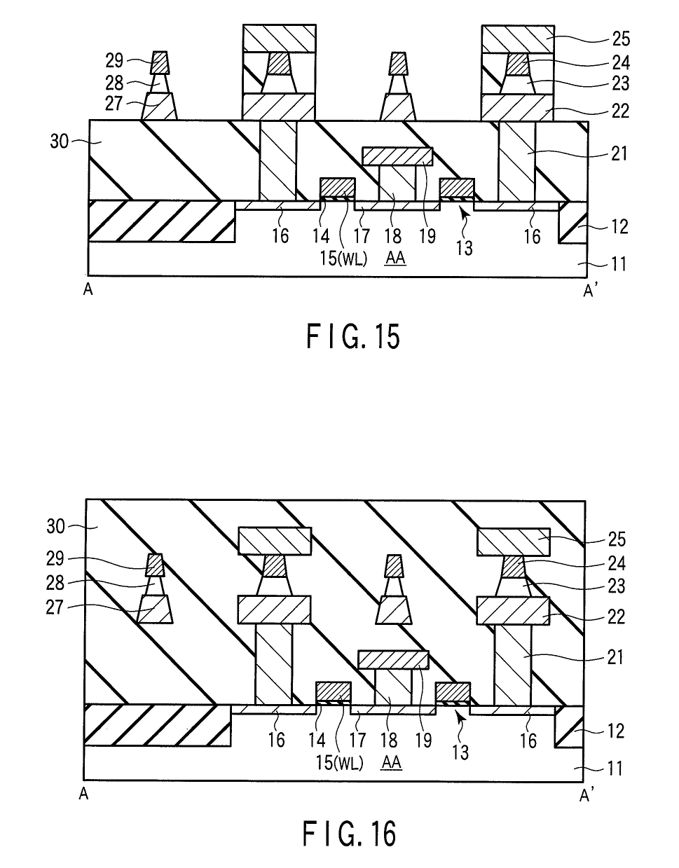

Next, as shown in FIG. 15, the upper electrode 25 and lower electrode 22 are processed with the resists 32 used as a mask by the RIE method, for example. The etching process is performed by first processing the upper electrode 25 by using the RIE method with the resists 32 used as a mask and then processing the lower electrode 22 by the RIE method again with the upper electrodes 25 used as a hard mask after removing the resists 32. At this time, the upper electrodes 25 and dummy elements 28 in areas in which the resists 32 are not formed are subjected to etching. In this case, since the dummy element 28 is thick and the upper electrode 29 is formed of a material used as a hard mask, the pattern and material are partly left behind in the memory area. Further, the dummy element 28 is subjected to etching and the size thereof becomes smaller than that of the MTJ element 23.

Next, as shown in FIG. 16, a step difference caused by etching is filled by means of the interlayer insulating layer 30 and the interlayer insulating layer 30 is made flat by a CMP method. At this time, the aspect ratio of the elements is suppressed by arranging the dummy element 28 between the MTJ elements 23. Thus, the interlayer insulating layer 30 can be easily made flat and the occurrence of dishing can be prevented by use of the CMP process.

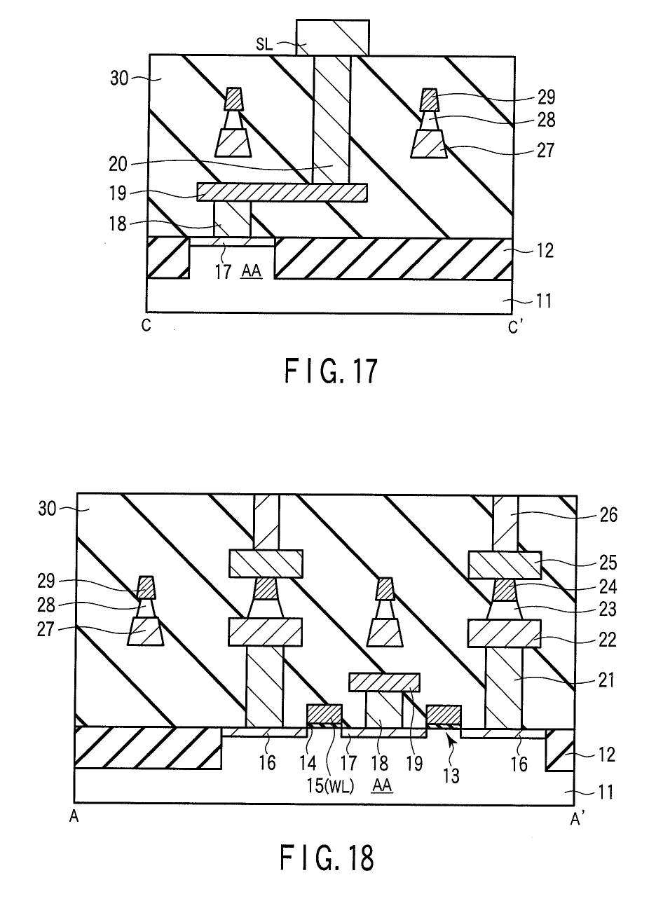

Then, as shown in FIG. 17, a contact plug 20 is formed on the lead line 19 in the interlayer insulating layer 30. Further, a conductive material used as source lines SL is deposited on the contact plug 20 and interlayer insulating layer 30. Then, the conductive material is processed by the lithography and RIE method to form source lines SL extending in the X direction.

Next, as shown in FIG. 18, an interlayer insulating layer 30 is deposited on the entire surface of the device. Then, contact plugs 26 are formed on the upper electrodes 25 in the interlayer insulating layer 30. Further, as shown in FIG. 3, a conductive material used as bit lines BL is deposited on the contact plugs 26 and interlayer insulating layer 30. Then, the conductive material is processed by the lithography and RIE method to form bit lines BL extending in the X direction. Thus, the MRAM according to the first embodiment is manufactured.

As described above in detail, in the first embodiment, the MRAM comprises the MTJ elements 23 and the dummy elements 28 having the same layer structure as the MTJ element 23 in the memory area. The element array having a combination of the MTJ elements 23 and dummy elements 28 has a lattice-form dense pattern shown in FIG. 1. That is, a resist pattern used at the time of processing the MTJ laminated film is formed of the lattice-form dense pattern. Further, the element array having the combination of the MTJ elements 23 and dummy elements 28 is arranged in a lattice-form dense pattern by processing the MTJ laminated film by using the resist pattern.

Therefore, according to the first embodiment, the resist pattern used to process the MTJ laminated film is a lattice-form dense pattern in which the distances between the resists in the lateral and vertical directions are the same and the distance with respect to the adjacent resist is uniform. Therefore, an influence caused by the interference of light from the surroundings is made uniform, and resists of substantially the same sizes can be formed. Further, the resist profile can be made approximately vertical and a variation in the resist shape is made small. Therefore, a variation in the shape of the MTJ element 23 formed by use of the resist pattern can be reduced. As a result, a variation in the magnetic characteristic of the MTJ element 23 can be made small and an MRAM having a large operation margin at the write or read time can be formed.

Conventionally, a gap between the MTJ elements 23 adjacent in the X direction is filled with an insulating layer, but the dummy element 28 is arranged between the MTJ elements 23 in this embodiment. If the dummy element 28 is not arranged between the MTJ elements 23 adjacent in the X direction, the distance therebetween becomes large. As a result, the aspect ratio becomes large and dishing occurs at the time of making the insulating layer flat. However, in this embodiment, since the aspect ratio of the adjacent elements (that is, the aspect ratio of the MTJ element 23 and dummy element 28) can be made small, the upper surface of an insulating layer can be made closer to a flat surface at the time of deposition thereof and the insulating layer can easily be made flat by a later CMP process. As a result, a variation in the resist shape in the lithography process can be reduced since the device is made flat.

Further, since the dummy element 28 is formed of the same magnetic layer as the MTJ element 23, the dummy element 28 can block a leakage magnetic field from the adjacent cell or other external magnetic field. As a result, an external magnetic field applied to the MTJ element 23 can be reduced and a variation in the magnetic characteristic and deterioration in the magnetic characteristic of the MTJ element 23 can be suppressed.

### Second Embodiment

The second embodiment is another example of the configuration of the first embodiment in which an active area AA and source line SL are electrically connected via one contact plug by forming the active area AA in a T-shaped form. The arrangement and configuration of MTJ elements 23 and dummy elements 28 are the same as those of the first embodiment.

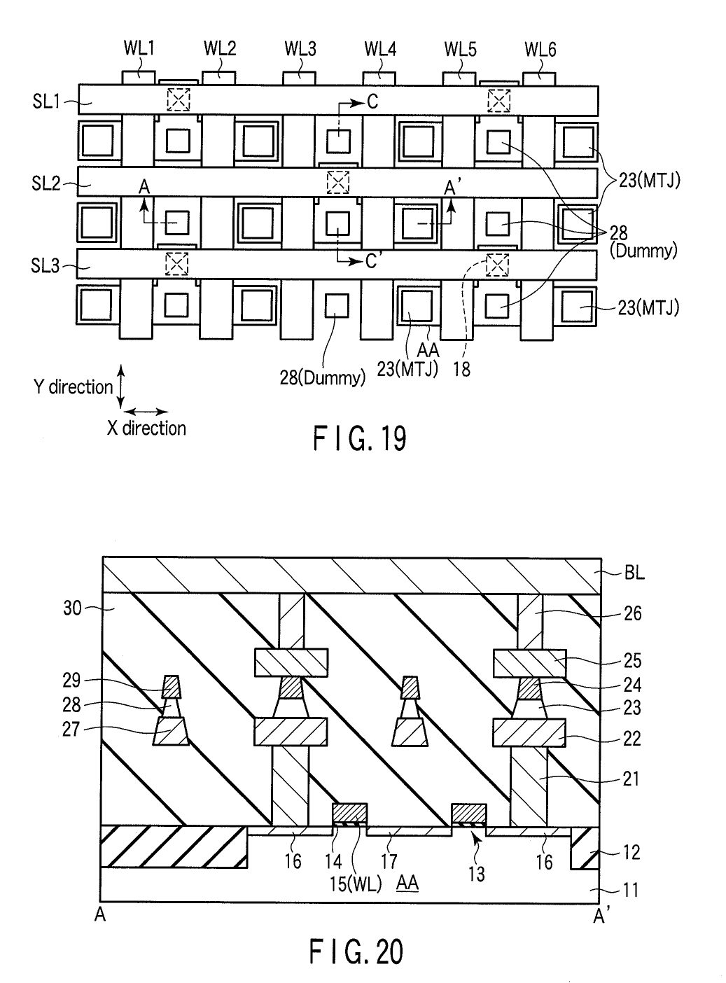

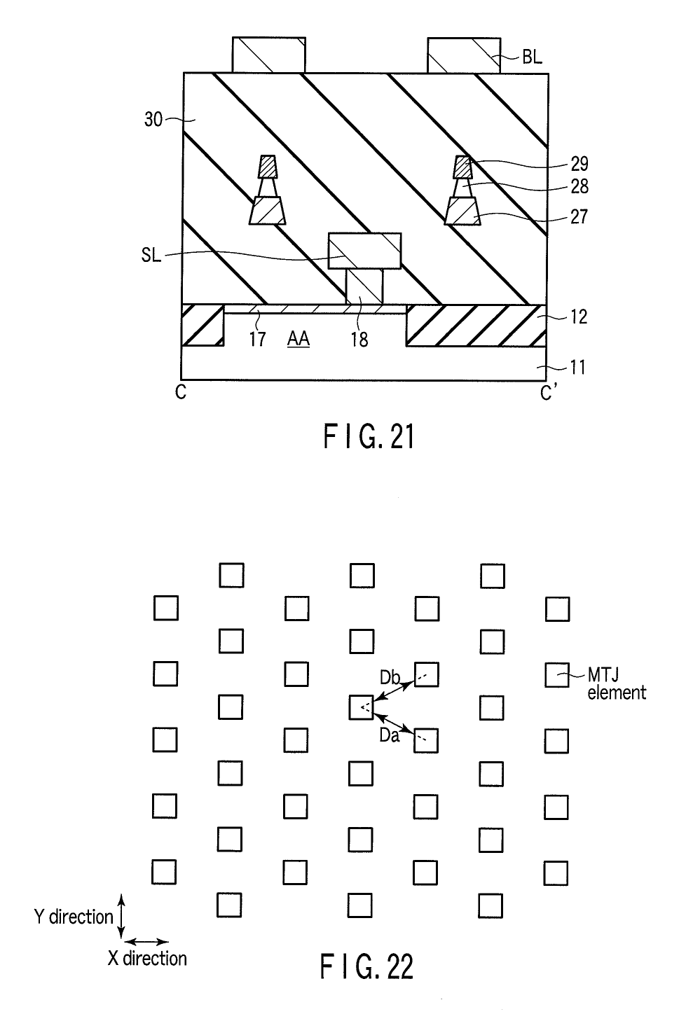

FIG. 19 is a plan view showing the configuration of an MRAM according to the second embodiment of this invention. FIG. 20 is a cross-sectional view showing the MRAM taken along the line A-A′ of FIG. 19. FIG. 21 is a cross-sectional view showing the MRAM taken along the line C-C′ line of FIG. 19.

Each active area AA is formed in a T-shaped form. Specifically, the active area comprises an extending portion that extends in an X direction and a protruding portion that protrudes in a Y direction from the central portion of the extending portion. A plurality of active areas AA adjacent in the X direction are arranged with an equal interval set therebetween (corresponding to two word lines). Further, two of the active areas AA adjacent in the Y direction are shifted by an amount corresponding to two word lines in the X direction. In other words, if a plurality of active areas AA arranged in the X direction are used as one row, adjacent active areas AA of two rows are arranged in a zigzag form. Two selection transistors 13 are provided in each active area AA.

A contact plug 18 is provided on a source/drain region 17 commonly used by the two selection transistors 13. A first line (source line SL) extending in the X direction is provided on the contact plug 18. Thus, in the MRAM of the second embodiment, the lead line 19 shown in the first embodiment becomes unnecessary.

The other configuration is the same as that of the first embodiment. As is clearly shown in FIGS. 20 and 21, bit lines BL are each arranged between the source lines SL above the MTJ elements 23 as the uppermost layer. However, in the layout diagram of FIG. 19, the bit lines BL are omitted in the drawing so that the layout of the MTJ elements and dummy elements can be easily understood.

A manufacturing method of the MRAM according to the second embodiment is similar to that of the first embodiment except that the shape of the active area AA and the level of the source line SL are different. When the MRAM is configured as shown in the second embodiment, the same effect as that of the first embodiment can be attained.

### Third Embodiment

The third embodiment is an example in which an MTJ element pattern different from that of the first embodiment is used. The layout of an ideal MTJ element pattern is shown in FIG. 22. The layout of FIG. 22 is a diamond-shaped dense pattern (rhombic dense pattern). Specifically, four adjacent MTJ elements configure a diamond shape (rhombic shape) and a plurality of diamond shapes are densely arranged with the two adjacent diamond shapes commonly having one side.

The diamond shape configured by the four MTJ elements has four sides with the same length. That is, the distances between the MTJ elements corresponding to the four sides are set equal. In FIG. 22, if the distance between a first MTJ element and a second MTJ element diagonally below the first MTJ element is set to Da and the distance between the first MTJ element and a third MTJ element diagonally above the first MTJ element is set to Db, Da=Db. Further, preferably, three neighboring MTJ elements configure an equilateral triangle. In this case, all of the distances between the four MTJ elements configuring the diamond shape are equal.

Since the distance between the adjacent MTJ elements is short and the element arrangement is uniform in the above dense pattern, an influence caused by the interference of light from the surroundings at the lithography process time tends to become uniform and patterns of substantially the same size can be easily formed. Further, a resist profile tends to be made vertical and a variation in the element shape becomes small.

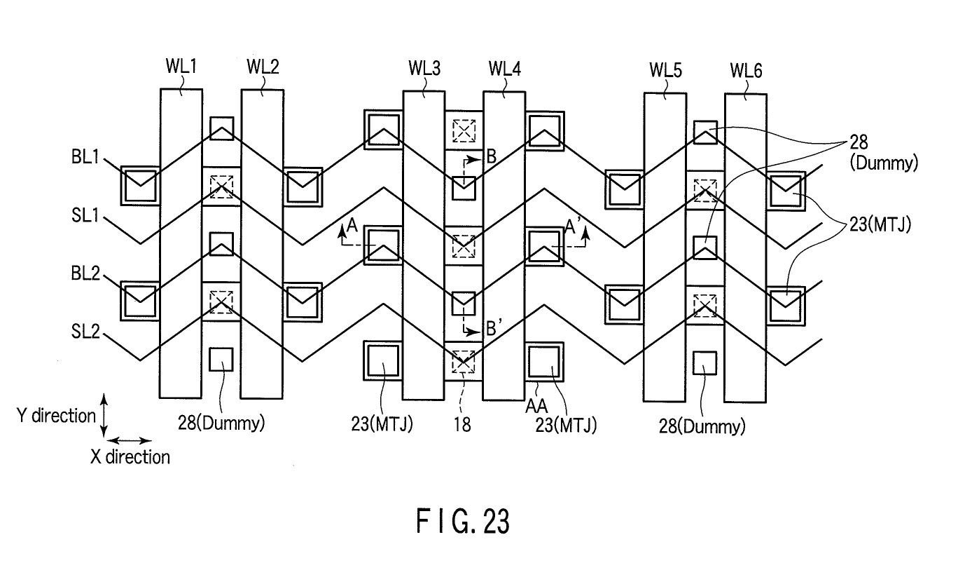

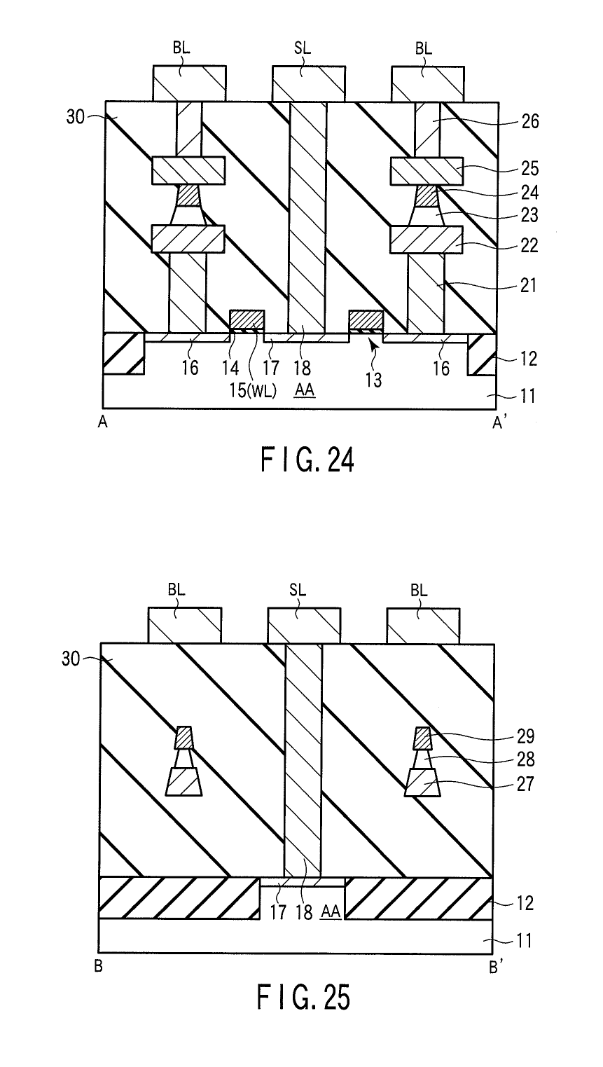

FIG. 23 shows an example in which the ideal pattern of FIG. 22 is applied to an MRAM and is a plan view showing the configuration of the MRAM. FIG. 24 is a cross-sectional view showing the MRAM taken along the line A-A′ of FIG. 23. FIG. 25 is a cross-sectional view showing the MRAM taken along the line B-B′ of FIG. 23.

When the ideal pattern of FIG. 22 is applied to an MRAM, dummy elements each of which is not used as a memory element and has the same configuration as that of the MTJ element are arranged between word lines WL. However, if the upper and lower portions of the dummy elements are not connected, no particular problem occurs in the operation of the MRAM.

A plurality of active areas (element areas) AA that are isolated by an element isolation insulating layer 12 are provided on a P-type semiconductor substrate 11. Each active area AA is a rectangle whose longitudinal direction is set in the X direction, for example, and the active areas are arranged at regular intervals in the Y direction. Further, the active areas AA that are adjacent in the X direction are arranged in a zigzag form. Two selection transistors 13 are provided in each active area AA. Therefore, the active area AA intersects with two word lines WL.

Contact plugs 18 are provided on source/drain regions 17 that are each commonly used by the two selection transistors 13. First lines (source lines SL) that extend in the X direction and are formed in a zigzag form (or in a wavy form) are provided on the contact plugs 18.

Contact plugs 21 are provided on source/drain regions 16. Lower electrodes 22 are formed on the respective contact plugs 21. MTJ elements 23 are provided on the lower electrodes 22. Contact layers 24 are formed on the respective MTJ elements 23. Upper electrodes 25 are provided on the Contact layers 24. Contact plugs 26 are formed on the respective upper electrodes 25. Second lines (bit lines BL) that extend in the X direction and are formed in a zigzag form (or in a wavy form) are provided on the respective contact plugs 26. A gap between a semiconductor substrate 11 and the bit lines BL is filled with an interlayer insulating layer 30.

The bit lines BL and source lines SL are formed of wiring layers of the same level. The bit lines BL and source lines SL of FIG. 23 are each indicated by a thin line so that the layout of the MTJ elements 23 and dummy elements 28 can be easily understood. However, in practice, as shown in FIGS. 24 and 25, the bit lines BL and source lines SL have preset wiring widths.

The dummy elements 28 are arranged between two word lines WL that intersect with the same active areas AA. The dummy element 28 is arranged with the same height as the MTJ element 23 and arranged in an isolated form in the interlayer insulating layer 30. That is, the dummy element 28 is not connected to any one of the lines and is electrically isolated. Further, as shown in FIG. 23, all of the dummy elements 28 are arranged in a memory area in which the MTJ elements 23 are arranged.

The dummy element 28 is sandwiched between a lower electrode 27 and an upper electrode 29. The dummy element 28 has the same laminated structure as the MTJ element 23. Further, the lower electrode 27 and upper electrode 29 are formed of the same material as that of the lower electrode 22 and contact layer 24 that sandwich the MTJ element 23. The size of the dummy element 28 is smaller than that of the MTJ element 23.

The MTJ element array is arranged in a stripe form and each line configuring the stripe is configured by a plurality of MTJ elements 23 arranged in the Y direction. Also, the dummy element array is arranged in a stripe form and each line configuring the stripe is configured by a plurality of dummy elements 28 arranged in the Y direction. An element array comprising a combination of the MTJ elements 23 and dummy elements 28 is a diamond-form dense pattern as shown in FIG. 22.

In a manufacturing method of the MTJ elements 23 and dummy elements 28 that are the main portions of the third embodiment, the diamond-form dense pattern shown in FIG. 22 is used as a resist pattern. By using the resist pattern and the same manufacturing process as that of the first embodiment, MTJ elements 23 and dummy elements 28 are formed. In other manufacturing steps, the same manufacturing method shown in the first embodiment can be applied to the third embodiment although the arrangement of active areas AA and the levels of the source lines SL are different.

As described above in detail, in the third embodiment, the MTJ elements 23 and the dummy elements 28 having the same layer configuration as the MTJ elements 23 are provided in the memory area. The element array having the combination of the MTJ elements 23 and dummy elements 28 has the diamond-form dense pattern shown in FIG. 22. That is, a resist pattern used at the time of processing the MTJ laminated film is formed according to a diamond-form dense pattern. Then, by processing the MTJ laminated film by use of the resist pattern, the element array having the combination of the MTJ elements 23 and dummy elements 28 is arranged into the diamond-form dense pattern.

Thus, according to the third embodiment, a variation in the shape of the MTJ elements 23 can be reduced. As a result, since a variation in the magnetic characteristic of the MTJ elements 23 can be reduced, an MRAM having a large operation margin at the write or read time can be configured. The other effects are the same as those of the first embodiment.

### Embodiment

As described before, as the resistance-change memory of this invention, various memories such as an ReRAM and PCRAM can be used in addition to the MRAM.

A variable resistance element configuring the ReRAM comprises a lower electrode, upper electrode and a recording layer sandwiched therebetween. The recording layer is applied with a current or voltage to take at least two resistance values as a bi-stable state at least at room temperatures. The memory operation of at least two values is realized by writing and reading the two stable resistance values.

A variable resistance element configuring the PCRAM comprises a lower electrode, heater layer, recording layer and upper electrode sequentially laminated in this order. The recording layer is configured by a phase-change material and is set into a crystallized state and amorphous state according to heat generated at the write time. The memory operation of at least two values is realized by writing and reading the resistance values in the crystallized state and amorphous state.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
variable resistance elements in a memory area and configured to store data according to a resistance variation, each of the variable resistance elements comprising a first terminal electrically connected to a first line and a second terminal electrically connected to a second line; and
dummy elements in the memory area, comprising the same material as the variable resistance element and electrically isolated.

2. The device of claim 1, wherein an array comprising the variable resistance elements and the dummy elements comprising the same distance between adjacent elements.

3. The device of claim 1, wherein an array comprising the variable resistance elements and the dummy elements is in a lattice pattern.

4. The device of claim 1, wherein an array comprising the variable resistance elements and the dummy elements is in a diamond-shape.

5. The device of claim 1, wherein three neighboring elements among the variable resistance elements and the dummy elements are in an equilateral triangle shape.

6. The device of claim 1, wherein the dummy element comprise the same plane shape as the variable resistance element.

7. The device of claim 1, wherein the dummy element is at the substantially same level as the variable resistance element.

8. The device of claim 1, wherein the dummy element comprises a size smaller than a size of the variable resistance element.

9. The device of claim 1, further comprising:
first lower electrodes and first upper electrodes comprising the variable resistance elements between the first lower electrodes and the first upper electrodes; and
second lower electrodes and second upper electrodes comprising the dummy elements between the second lower electrodes and the second upper electrodes.

10. The device of claim 1, wherein
each variable resistance element comprises a fixed layer comprising a fixed magnetization direction, a recording layer comprising variable magnetization directions and a nonmagnetic layer between the fixed layer and the recording layer, and
each the dummy element comprises the same laminated structure as the variable resistance element.

11. The device of claim 1, further comprising a selection transistor connected between the second line and each variable resistance element,
wherein the selection transistor is in an active area of a substrate.

12. The device of claim 11, wherein
the selection transistor comprises first and second diffusion regions,
the first diffusion region is connected to the variable resistance element via a contact plug, and
the second diffusion region is connected to the second line via a contact plug.

13. The device of claim 11, wherein two selection transistors are configured to share one diffusion region in one active area.

14. A manufacturing method of a semiconductor memory device, the method comprising:
forming contact plugs in a first insulating layer;
sequentially depositing a variable resistance material and contact material on the first insulating layer and the contact plugs;
forming a resist pattern comprising first resists with the same distance between adjacent first resists on the contact material; and
etching the contact material and the variable resistance material with the resist pattern used as a mask in order to form variable resistance elements electrically connected to the contact plugs and dummy elements on the first insulating layer.

15. The method of claim 14, wherein the resist pattern is in a lattice pattern.

16. The method of claim 14, wherein the resist pattern is in a diamond-shape.

17. The method of claim 14, further comprising:
depositing a lower electrode material between the first insulating layer and contact plugs and the variable resistance material;
depositing an upper electrode material on the contact material;
forming second resists on the upper electrode material and above the variable resistance elements; and
etching the lower electrode material and upper electrode material with the second resists used as a mask.

18. The method of claim 14, further comprising:
embedding the variable resistance elements and the dummy elements in a second insulating layer; and
forming lines electrically connected to the variable resistance elements on the second insulating layer.

19. The method of claim 14, further comprising:
forming selection transistors in a semiconductor substrate; and
forming the first insulating layer on the semiconductor substrate,
wherein the contact plugs are on diffusion regions of the selection transistors.
